(19) United States
(12) Patent Application Publication
(10) Pub. No.: US 2016/0348240 A1
(43) Pub. Date: Dec. 1, 2016

(54) HIGH SPEED EPI SYSTEM AND CHAMBER CONCEPTS

(71) Applicant: APPLIED MATERIALS, INC, Santa Clara, CA (US)

(72) Inventors: Brian H. BURROWS, San Jose, CA (US); Lance A. SCUDDER, Sunnyvale, CA (US); Kashif MAQSOOD, San Francisco, CA (US); Roger N. ANDERSON, San Martin, CA (US); Sumedh Dattatraya ACHARYA, Bangalore (IN)

(21) Appl. No.: 15/111,541

(22) PCT Filed: Jan. 6, 2015
(86) PCT No.: PCT/US2015/010357

§ 371 Date: Jul. 14, 2016

Related U.S. Application Data
(60) Provisional application No. 61/932,035, filed on Jan. 27, 2014.

(51) Int. Cl. C23C 16/458; C23C 16/48; C23C 16/24; H01L 21/677; H01L 21/67

(52) U.S. Cl. CPC C23C 16/4584; H01L 21/67757; H01L 21/67115; H01L 21/6719; C23C 16/24; C23C 16/482

(57) ABSTRACT

Embodiments described herein generally relate to a batch processing chamber. The batch processing chamber includes a lid, a chamber wall and a bottom that define a processing region. A cassette including a stack of susceptors for supporting substrates is disposed in the processing region. The edge of the cassette is coupled to a plurality of shafts and the shafts are coupled to a rotor. During operation, the rotor rotates the cassette to improve deposition uniformity. A heating element is disposed on the chamber wall and a plurality of gas inlets is disposed through the heating element on the chamber wall. Each gas inlet is substantially perpendicular to the chamber wall.

### BACKGROUND

1. Field

Embodiments described herein generally relate to an apparatus for epitaxial deposition. More specifically, embodiments described herein relate to a rotating batch processing chamber.

2. Description of the Related Art

Semiconductor substrates are processed for a wide variety of applications, including the fabrication of integrated devices and microdevices. One method of processing substrates includes depositing a material, such as a dielectric material or a conductive metal, on an upper surface of the substrate. For example, epitaxy is a deposition process that grows a thin, ultra-pure layer, usually of silicon or germanium on a surface of a substrate. The material may be deposited in a lateral flow chamber by flowing a process gas parallel to the surface of a substrate positioned on a support, and thermally decomposing the process gas to deposit a material from the gas onto the substrate surface.

In order to increase throughput and reduce cost, an improved apparatus for epitaxial deposition is needed.

### SUMMARY

Embodiments described herein generally relate to a batch processing chamber. The batch processing chamber includes a lid, a chamber wall and a bottom that define a processing region. A cassette including a stack of susceptors for supporting substrates is disposed in the processing region. The edge of the cassette is coupled to a plurality of shafts and the shafts are coupled to a rotor. During operation, the rotor rotates the cassette to improve deposition uniformity. A heating element is disposed on the chamber wall and a plurality of gas inlets is disposed through the heating element on the chamber wall. Each gas inlet is substantially perpendicular to the chamber wall.

In one embodiment, a rotating batch processing chamber is disclosed. The rotating batch processing chamber includes a chamber wall, a bottom, and a lid. The chamber wall, the bottom and the lid define a processing region. The chamber further includes a cassette configured to hold a plurality of substrates disposed in the processing region, a plurality of shafts coupled to an edge of the cassette, a rotor coupled to the plurality of shafts, a stator coupled to the rotor, and a first heating member disposed adjacent to the chamber wall.

In another embodiment, a rotating batch processing chamber is disclosed. The rotating batch processing chamber includes a chamber wall, a bottom and a lid. The chamber wall, the bottom and the lid define a processing region. The chamber further includes a cassette configured to hold a plurality of substrates disposed in the processing region, a plurality of shafts coupled to an edge of the cassette, a rotor coupled to the plurality of shafts, a stator coupled to the rotor, a first heating member disposed adjacent to the chamber wall and a plurality of gas inlets disposed through the first heating member on the chamber wall. Each of the plurality of gas inlets is substantially perpendicular to the chamber wall.

In another embodiment, a rotating batch processing chamber is disclosed. The rotating batch processing chamber includes a chamber wall, a bottom, and a lid. The chamber wall, the bottom and the lid define a processing region. The chamber further includes a cassette configured to hold a plurality of substrates disposed in the processing region, a first heating member disposed adjacent to the chamber wall, and a plurality of gas inlets disposed through the first heating member on the chamber wall. Each of the plurality of gas inlets is perpendicular to the chamber wall. The chamber further includes a chamber liner disposed between the cassette and the chamber wall and a plurality of gas lines disposed between the chamber liner and the chamber wall, where each of the plurality of gas lines is substantially parallel to the chamber wall.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 (FIG. 1 in drawings) is a cross sectional perspective view of a processing chamber according to one embodiment.

FIGS. 2A-2B (FIG. 2A, FIG. 2B in drawings) are cross sectional side views of the processing chamber according to one embodiment,

FIG. 3 (FIG. 3 in drawings) is a perspective view of the chamber according to one embodiment.

FIG. 4 (FIG. 4 in drawings) is a cross sectional perspective view of gas inlets according to one embodiment.

FIG. 5 (FIG. 5 in drawings) is a cross sectional perspective view of a plurality of processing chambers according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Generally, a silicon CVD deposition process may proceed within a mass transport regime, in which process gases provided to a substrate diffuse across a boundary layer, adsorb onto the surface of the substrate, migrate and dissociate on the surface of the substrate, nucleate and grow from the surface of the substrate, exit the surface of the substrate by desorption, and diffuse back across the boundary layer. To increase throughput and reduce cost, multiple template substrates may be placed in a rotating batch processing chamber so that a silicon layer is deposited on an upper surface and a lower surface of each of the substrates inside the processing chamber.

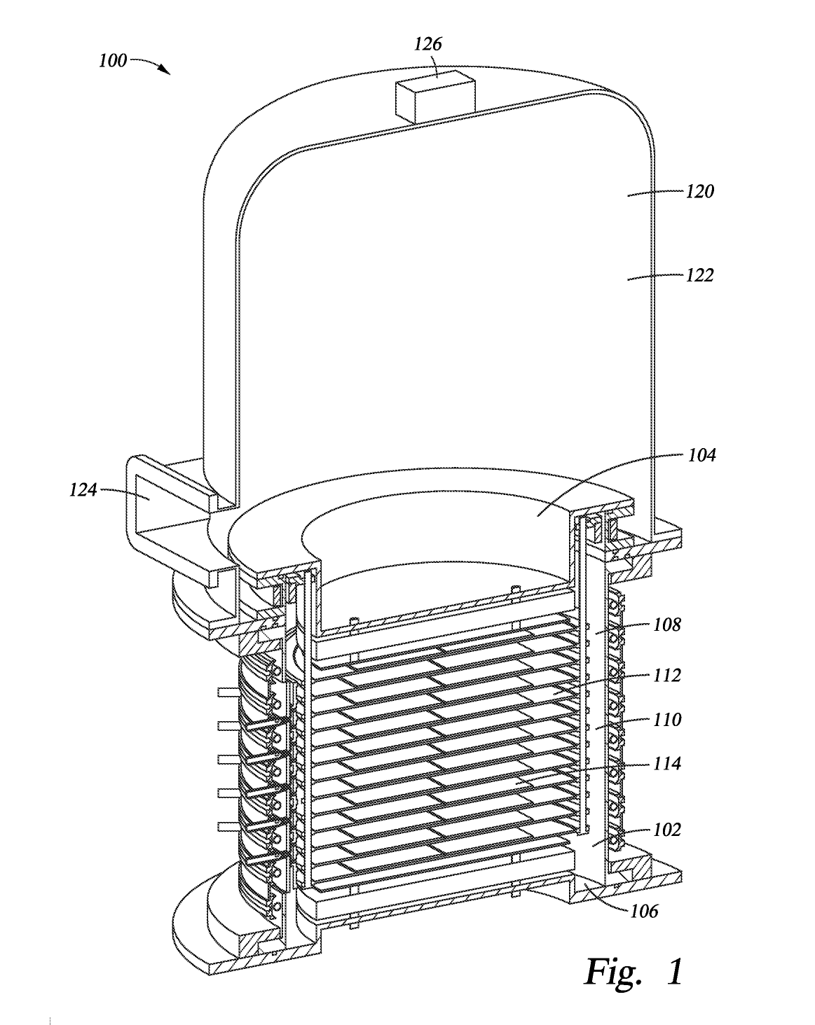

FIG. 1 is a cross sectional perspective view of a processing chamber 100 according to one embodiment. The processing chamber 100 has a chamber wall 102, a lid 104 and a bottom 106. The chamber wall 102 may be cylindrical and may be made of clear quartz. The chamber wall 102, lid 104 and bottom 106 may define a processing region 108, and a cassette 110 may be disposed within the processing region 108. The cassette 110 may include a stack of susceptors 112, or a plurality of susceptors 112 in a stack-like configuration, and each susceptor 112 may hold one or more substrates 114. The susceptors 112 may be configured to hold the substrates 114 for either single sided deposition or dual sided deposition. The cassette 110 may rotate continuously during the deposition process for improved deposition uniformity.

Above the lid 104 is a top cover 120 and a loading region 122 may be defined by the top cover 120. An opening 124 may be formed in the top cover 120 and a lift mechanism 126 may be disposed on the top cover 120 for lifting the cassette 110. During loading/unloading of the substrates 114, the cassette 110 is lifted into the loading region 122, and substrates 114 are loaded/unloaded through the opening 124. The loading/unloading of the substrates 114 is not limited to lifting the cassette 110. The loading/unloading of the substrates 114 may be performed by dropping the cassette 110 into a loading region that is defined by a bottom cover (not shown) that is disposed below the bottom 106.

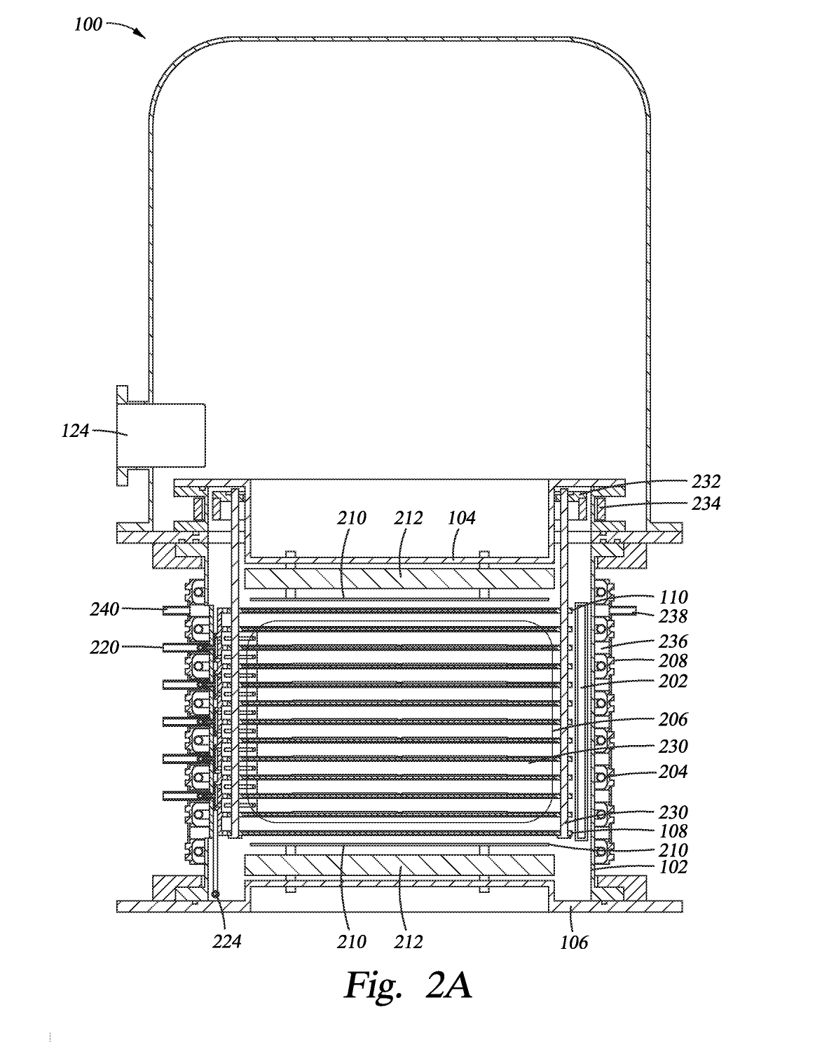

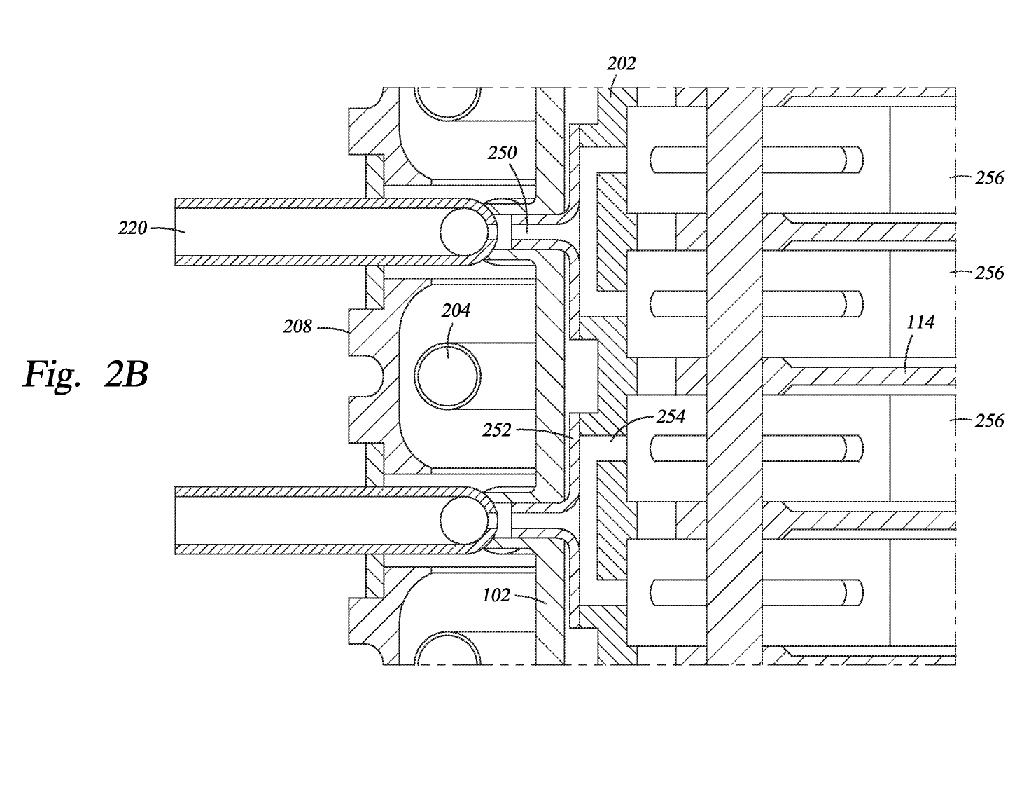

FIG. 2A is a cross sectional side view of the processing chamber 100. A heating element 204 may be disposed adjacent to the chamber wall 102 for providing thermal energy to the processing region 108. The heating element 204 may be any suitable heating element. In one embodiment, the heating element 204 includes a plurality of infrared (“IR”) lamps surrounding the cassette 110. In one embodiment, the IR lamps surround the chamber wall 102. The arrangement of the lamps may vary depending on the process. In the embodiment where the chamber wall 102 is cylindrical, the IR lamps are circular. The IR lamps may be stacked to provide axial multi-zone heating, as shown in FIG. 2A. In another embodiment, each lamp is a linear lamp that is disposed parallel to the chamber wall 102 (perpendicular to the susceptors 112), and a plurality of the linear lamps is arranged around the circumference of the chamber wall 102. Additionally or alternatively, the heating element 204 may include one or more inductive heaters. The inductive heater may be a ferrite core coiled around the cassette 110, such as around the chamber wall 102. One or more wires may be wrapped around the ferrite core and each wire may be connected to a power source to form an electric circuit.

A reflector 208 may surround the heating element 204, such as the plurality of IR lamps, to more efficiently control heating the processing region 108. In one embodiment, the reflector 208 includes a plurality of curved annular rings and each ring circumscribes the outer circumference of each IR lamp. Thus, heat generated from the IR lamp is directed toward the processing region 108. The reflector 208 may have cooling channels 236 disposed therein. Each cooling channel 236 may have an inlet 238 and an outlet 240 and the reflector 208 may be cooled with a coolant such as water flowing from the inlet 238 through the cooling channels 236 and out of the outlet 240. A chamber liner 202 is disposed between the cassette 110 and the chamber wall 102. The chamber liner 202 may have the similar shape as the chamber wall 102, such as cylindrical and can provide thermal uniformity and create an isothermal zone 206 within the processing region 108. The chamber liner 202 may be made of silicon carbide coated graphite.

In addition to the heating element 204, heating element 210 may be disposed above and/or below the cassette 110 to provide radial multi-zone heating. The heating element 210 may be any suitable heating element. In one embodiment, the heating element 210 is a resistive heating element that is made of solid silicon carbide or silicon carbide coated graphite. A thermal insulator 212 may be disposed between the heating element 210 and the lid 104/bottom 106.

A plurality of gas inlets 220 may be disposed through the heating element 204 on the chamber wall 102. In one embodiment, the gas inlets 220 are substantially perpendicular to the chamber wall 102. In the embodiment where the heating element 204 is a plurality of IR lamps, the gas inlets 220 and the IR lamps are interleaved, as shown in FIG. 2A. In other words, each gas inlet 220 is disposed between two adjacent IR lamps. A plurality of purging gas lines 224 may be disposed between the chamber liner 202 and the chamber wall 102. The purging gas lines 224 may be substantially parallel to the chamber wall 102.

The edge of the cassette 110 may be coupled to a plurality of shafts 230 which are coupled to a rotor 232. The rotor 232 may be coupled to a stator 234. In one embodiment, the rotor 232 and the stator 234 are both permanent magnets, and the rotor 232 is magnetically coupled to the stator 234. The cassette 110 levitates and rotates continuously during operation. In another embodiment, the rotor 232 and the stator 234 are parts of a linear arc motor, and the linear arc motor rotates the cassette 110 continuously during operation.

FIG. 2B is an enlarged cross sectional side view of the gas inlets 220 according to one embodiment. As shown in FIG. 2B, processing gases are introduced from each gas inlet 220, through an opening 250 formed in the chamber wall 102 and openings 254 formed in the chamber liner 202 into two processing volumes 256. Each processing volume 256 may be between two substrates 114. During a dual sided deposition process, two substrate surfaces are processed in each processing volume 256, i.e., the lower surface of a first substrate and the upper surface of a second substrate disposed below the first substrate. Therefore, each gas inlet 220 controls the processing gas flow for processing four surfaces (more surfaces if multiple substrates are disposed on the same susceptor). The openings 250 in the chamber wall 102 and the inside surface of the chamber wall 102 may be lined with an insert 252. The insert 252 may be made of quartz.

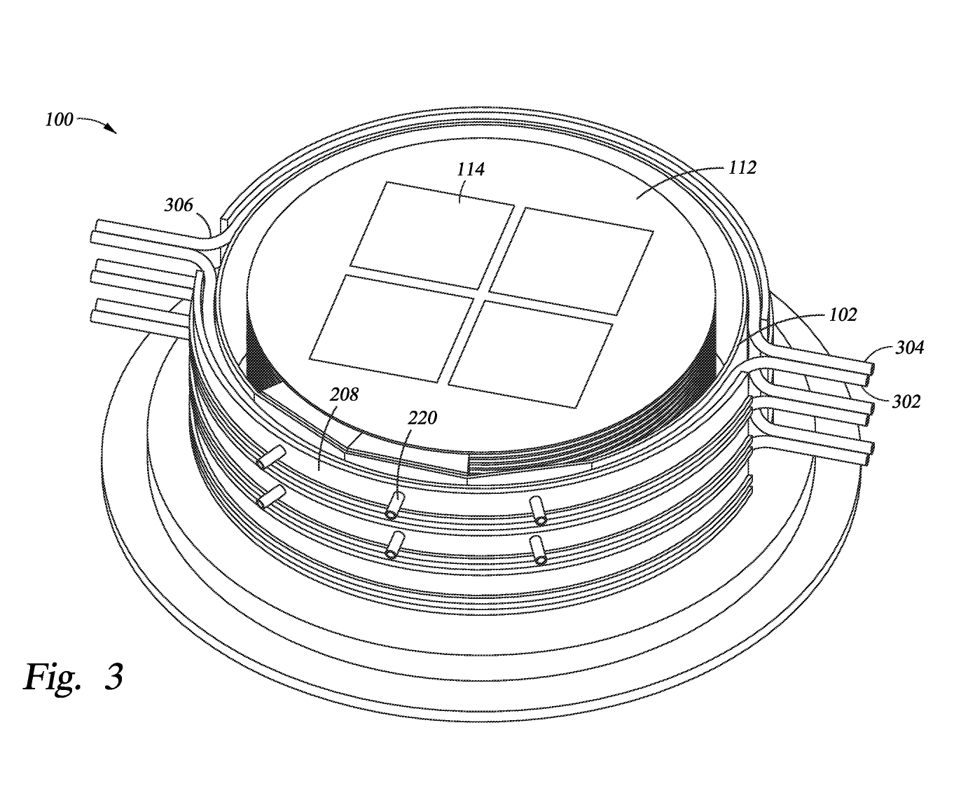

FIG. 3 is a perspective view of the processing chamber 100 according to one embodiment. As shown in FIG. 3, each susceptor 112 supports four substrates 114. A plurality of cooling tubes 302 may be disposed between the reflector 208 and the chamber wall 102. The cooling tubes 302 provides cooling for the heating element 204 and in the embodiment where the heating element 204 is a plurality of IR lamps, the cooling tubes 302 may be axially interleaved with the IR lamps. In other words, each cooling tube 302 may be positioned between every adjacent pair of IR lamps. Each cooling tube 302 has an inlet 304 and an outlet 306. Cooling air may be flowed from the inlet 304 to the outlet 306 to cool the heating element 204.

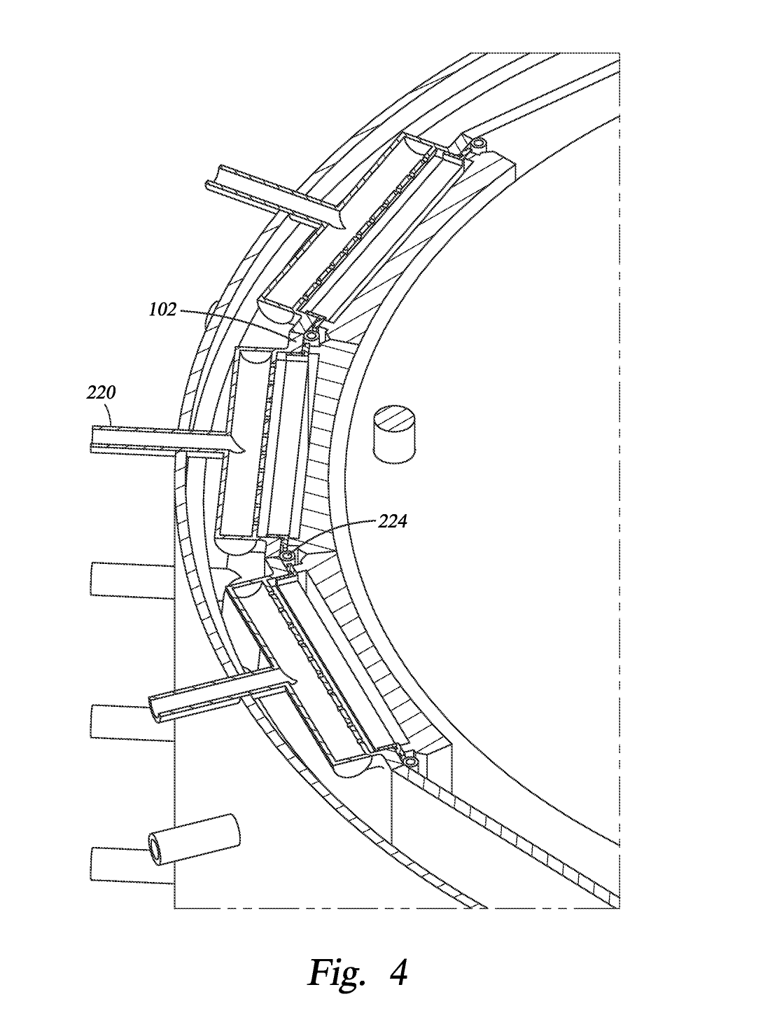

FIG. 4 is a cross sectional perspective view of gas inlets 220 according to one embodiment. Multiple gas inlets 220 may be disposed on the same level to provide a more uniform gas flow across the substrates 114 disposed on the susceptors 112. In the embodiment shown in FIG. 4, there are three gas inlets 220 on each level. The purging gas lines 224 may be disposed between the gas inlets 220. Again the gas inlets 220 are substantially perpendicular to the chamber wall 102 and the purging gas lines 224 are substantially parallel to the chamber wall 102.

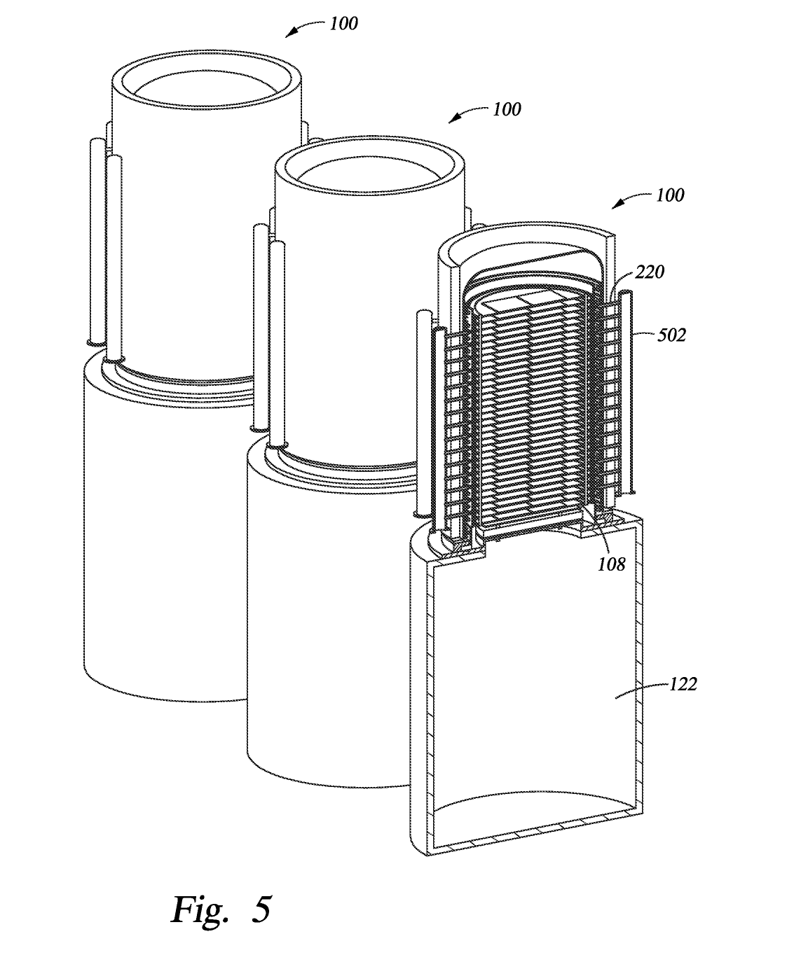

FIG. 5 is a cross sectional perspective view of a plurality of processing chambers 100 according to one embodiment. Each processing chamber 100 has the loading region 122 disposed below the processing region 108. A main gas inlet line 502 is connected to each column of gas inlets 220. Processing gas may be introduced to the main gas inlet line 502 from the top or the bottom, and then flowed into each gas inlet 220.

While the foregoing is directed to embodiments of the present invention, other and further embodiments of the invention may be devised without departing from the basic scope thereof, and the scope thereof is determined by the claims that follow.

1. A rotating batch processing chamber, comprising:
a chamber wall;
a bottom;
a lid, wherein the chamber wall, the bottom and the lid define a processing region;
a cassette configured to hold a plurality of substrates disposed in the processing region;
a plurality of shafts coupled to an edge of the cassette;
a rotor coupled to the plurality of shafts;
a stator coupled to the rotor; and
a first heating member disposed adjacent to the chamber wall.

2. The rotating batch processing chamber of claim 1, wherein the first heating member includes a plurality of infrared lamps.

3. The rotating batch processing chamber of claim 2, wherein the chamber wall is cylindrical, the plurality of infrared lamps are circular and the plurality of infrared lamps surrounds the chamber wall.

4. The rotating batch processing chamber of claim 1, further comprising a second heating element disposed above and/or below the cassette.

5. The rotating batch processing chamber of claim 1, further comprising a reflector surrounding the first heating element.

6. A rotating batch processing chamber, comprising:
a chamber wall;
a bottom;
a lid, wherein the chamber wall, the bottom and the lid define a processing region;
a cassette configured to hold a plurality of substrates disposed in the processing region;
a plurality of shafts coupled to an edge of the cassette;
a rotor coupled to the plurality of shafts;
a stator coupled to the rotor;
a first heating member disposed adjacent to the chamber wall; and
a plurality of gas inlets disposed through the first heating member on the chamber wall, wherein each of the plurality of gas inlets is substantially perpendicular to the chamber wall.

7. The rotating batch processing chamber of claim 6, wherein the first heating member includes a plurality of infrared lamps.

8. The rotating batch processing chamber of claim 7, wherein the chamber wall is cylindrical, the plurality of infrared lamps are circular and the plurality of infrared lamps surrounds the chamber wall.

9. The rotating batch processing chamber of claim 6, wherein the first heating member includes one or more inductive heaters.

10. The rotating batch processing chamber of claim 6, further comprising a second heating element disposed above and/or below the cassette.

11. The rotating batch processing chamber of claim 6, wherein the rotor and the stator are permanent magnets, and the rotor is magnetically coupled to the stator.

12. The rotating batch processing chamber of claim 6, further comprising a linear arc motor coupled to the plurality of shafts, wherein the linear arc motor includes the rotor and the stator.

13. A rotating batch processing chamber, comprising:
a chamber wall;
a bottom;
a lid, wherein the chamber wall, the bottom and the lid define a processing region;
a cassette configured to hold a plurality of substrates disposed in the processing region;
a first heating member disposed adjacent to the chamber wall;
a plurality of gas inlets disposed through the first heating member on the chamber wall, wherein each of the plurality of gas inlets is perpendicular to the chamber wall;
a chamber liner disposed between the cassette and the chamber wall; and
a plurality of gas lines disposed between the chamber liner and the chamber wall, wherein each of the plurality of gas lines is substantially parallel to the chamber wall.

14. The rotating batch processing chamber of claim 13, wherein the first heating member includes a plurality of infrared lamps.

15. The rotating batch processing chamber of claim 13, further comprising a second heating element disposed above and/or below the cassette.
